(19) United States
(12) Patent Application Publication
(10) Pub. No.: US 2019/0270528 A1
(43) Pub. Date: Sep. 5, 2019

(54) Ruggedized Solar Panel for Use on a Kinetically Launched Satellite

(71) Applicant: SpinLaunch Inc., Sunnyvale, CA (US)

(72) Inventors: Carl Lawhon, Sunnyvale, CA (US); Maxim Clarke, Sunnyvale, CA (US); Jonathan Yaney, Sunnyvale, CA (US)

(21) Appl. No.: 15/910,825

(22) Filed: Mar. 2, 2018

(51) Int. Cl. B64G 1/44; H02S 10/40; H02S 30/10; B64G 1/22; B32B 7/12; B32B 5/02; B32B 3/12; B32B 5/18

(52) U.S. Cl. CPC B64G 1/443; H02S 10/40; H02S 30/10; B64G 1/222; H01L 31/041; B32B 5/02; B32B 3/12; B32B 5/18; B32B 7/12

(57) ABSTRACT

Ruggedized solar panels for use on top of a satellite configured for a kinetic space launch are disclosed. The solar panels are able to maintain structural integrity and functionality of the solar cells under high acceleration forces generated during kinetic launch, including acceleration forces of >5,000 times Earth's gravity in a single direction of loading. The solar panels are ruggedized to withstand this level of acceleration force during launch via stiffening mechanisms, such as lamination of the solar panel into a sandwich panel structure, and/or use of support beams under a solar panel. Further, a high-specific-stiffness composition of the solar panel aids the solar panel in remaining flat during launch so it does not deflect inwards and damage the solar cells.

### CROSS-REFERENCE TO RELATED APPLICATIONS

The present application is related to co-pending U.S. patent application Ser. No. 15/133,105 filed on Apr. 19, 2016 and entitled “Circular Mass Accelerator”. The disclosure of the above-referenced application is incorporated by reference herein in its entirety for all purposes.

### FIELD OF THE INVENTION

The present disclosure relates generally to the field of kinetically launched satellites, and more specifically to methods for fixturing a solar panel on top of a kinetically launched satellite, such that it maintains structural integrity during the high acceleration forces generated during a kinetic launch.

### SUMMARY

This summary is provided to introduce a selection of concepts in a simplified form that are further described in the Detailed Description below. This summary is not intended to identify key features or essential features of the claimed subject matter, nor is it intended to be used as an aid in determining the scope of the claimed subject matter.

Various embodiments of the present disclosure may be directed to methods and apparatuses for providing ruggedized solar panels for use with satellites configured for a kinetic space launch. The solar panels are able to maintain structural integrity and functionality of the solar cells on the panels under high acceleration forces generated during kinetic launch, including acceleration forces of >5,000 times Earth's gravity in a single direction of loading. The solar panels are ruggedized to withstand this level of acceleration force during launch via stiffening mechanisms, such as lamination of the solar panels into a sandwich panel structure, and/or use of support beams under a solar panel. The support beams can be of varying shapes, such as arched or straight-edged. The present disclosure allows for the launch of satellites via a kinetic launcher, which generates loading forces in the opposite direction of acceleration.

Further, a high-specific-stiffness composition of the solar panel aids the solar panel in supporting its own weight and remaining flat during launch so it does not deflect inwards and damage the solar cells on the solar panel.

Other examples and embodiments are discussed in further detail below.

### BRIEF DESCRIPTION OF THE DRAWINGS

Certain embodiments of the present disclosure are illustrated by the accompanying figures. It will be understood that the figures are not necessarily to scale and that details not necessary for an understanding, or that render other details difficult to perceive, may be omitted. Embodiments are illustrated by way of example and not by limitation in the figures of the accompanying drawings, in which like references indicate similar elements.

FIG. 1 depicts a side view of an exemplary embodiment of a solar cell affixed on a panel on top of a kinetically launched satellite.

FIG. 2 depicts a side view of an exemplary embodiment of a solar cell affixed on a deployable solar panel on a kinetically launched satellite.

FIG. 3 depicts an exemplary method for providing ruggedized solar cells on a kinetically launched satellite.

FIG. 4 depicts an exemplary embodiment of a solar cell fixture method on a top panel of a kinetically launched satellite, utilizing support beams.

FIG. 5 depicts an exemplary embodiment of a solar cell fixture method on a top panel of a kinetically launched satellite, without utilizing any support beams.

FIGS. 6A and 6B depict an exemplary embodiment of a deployable solar panel fixtured on a top panel of a kinetically launched satellite, utilizing support beams.

FIGS. 6C and 6D depict another view of an exemplary embodiment of a deployable solar panel fixtured on a top panel of a kinetically launched satellite, utilizing support beams.

### DETAILED DESCRIPTION

The following detailed description includes references to the accompanying drawings, which form a part of the detailed description. The drawings show illustrations in accordance with example embodiments. These example embodiments, which are also referred to herein as “examples,” are described in enough detail to enable those skilled in the art to practice the present subject matter. The embodiments can be combined, other embodiments can be utilized, or structural, logical, and other changes can be made without departure from the scope of what is claimed. The following detailed description is therefore not to be taken in a limiting sense, and the scope is defined by the appended claims and their equivalents.

The corresponding structures, materials, acts, and equivalents of all means or step plus function elements in the claims below are intended to include any structure, material, or act for performing the function in combination with other claimed elements as specifically claimed. The description of the present technology has been presented for purposes of illustration and description, but is not intended to be exhaustive or limited to the present technology in the form disclosed. Many modifications and variations will be apparent to those of ordinary skill in the art without departing from the scope and spirit of the present technology. Exemplary embodiments are chosen and described in order to best explain the principles of the present technology and its practical application, and to enable others of ordinary skill in the art to understand the present technology for various embodiments with various modifications as are suited to the particular use contemplated.

Aspects of the present disclosure are described herein with reference to flowchart illustrations and/or block diagrams of methods, and apparatus (systems) according to embodiments of the present technology. The flowchart illustrations and/or block diagrams in the Figures illustrate the architecture, environment, functionality, and operation of possible implementations of systems, methods and apparatuses according to various embodiments of the present disclosure. It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

In the following description, for purposes of explanation and not limitation, specific details are set forth, such as particular embodiments, procedures, techniques, etc. in order to provide a thorough understanding of the present invention. However, it will be apparent to one skilled in the art that the present invention may be practiced in other embodiments that depart from these specific details.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” or “according to one embodiment” (or other phrases having similar import) at various places throughout this specification are not necessarily all referring to the same embodiment. Furthermore, the particular features, structures, or characteristics may be combined in any suitable manner in one or more embodiments. Furthermore, depending on the context of discussion herein, a singular term may include its plural forms and a plural term may include its singular form. Similarly, a hyphenated term (e.g., “on-demand”) may be occasionally interchangeably used with its non-hyphenated version (e.g., “on demand”), a capitalized entry (e.g., “Panel”) may be interchangeably used with its non-capitalized version (e.g., “panel”). Such occasional interchangeable uses shall not be considered inconsistent with each other.

Also, some embodiments may be described in terms of “means for” performing a task or set of tasks. It will be understood that a “means for” may be expressed herein in terms of a structure, device, composition, or combinations thereof.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Satellites are used for many purposes, and are traditionally launched into Earth orbit or beyond via a rocket-propelled launch vehicle. Traditional rockets carry massive quantities of propellant to deliver payloads that are minute fractions of the overall vehicle sizes and weights. All of the performance and risks are built into a precision, often single-use vehicle that must be highly reliable and inherently costly.

While incremental gains have been made in rocket technologies to reduce space launch costs, alternative approaches are necessary to reduce those costs and increase launch rates by the orders of magnitude necessary to create exponential growth in the space transportation industry. Since the beginning of the space program, ground-based non-rocket launch systems such as rail guns and ram accelerators have been proposed to achieve this. Additionally, centripetal launchers, such as one described in related U.S. patent application Ser. No. 15/133,105 filed on Apr. 19, 2016 and entitled “Circular Mass Accelerator” may be used instead of a rocket-propelled space launch.

Use of kinetic energy to provide the energy needed to launch a payload into space (instead of rocket propulsion), requires high acceleration forces to be generated at launch to ensure the payload has sufficient velocity to actually reach Earth orbit or beyond. Kinetically launched satellites are satellites launched into Earth orbit with the assistance of a ground-based mass acceleration technology, such as a centripetal launcher. Kinetic launchers subject the satellites to quasi-static acceleration loading in excess of 5,000 times Earth's gravity (G-force). As such, kinetically launched satellites must be designed to withstand this extreme high acceleration loading force generated at launch from Earth. As used herein, quasi-static acceleration is acceleration that is relatively constant for an extended period of time and acts primarily in a single direction through the satellite structure. As such, this does not include vibrational loading. Further, as used herein, the “top” of a satellite faces the direction of acceleration and opposes the loading direction. The “bottom” of a satellite opposes the “top” of the satellite and the “sides” of the satellite are perpendicular to the acceleration vector.

There are many different ways to accelerate a satellite via a kinetic launcher. That is, the satellite can be held from a top surface, bottom surface, or one or more side surfaces. Each scenario generates different acceleration forces. Embodiments of the present disclosure describe satellites that experience compression loading during kinetic launch, i.e. loading forces that compress the satellite, as opposed to loading forces that pull the satellite apart or shear the satellite from the sides.

Satellites that are launched into Earth orbit without a kinetic launcher, such as satellites launched via rocket propelled systems, primarily need to withstand vibrational loading during launch. Satellites undergoing orbital insertion via rocket launch will undergo a maximum of 10 times Earth gravity of quasi-static loading. As such, the loading force that the satellite needs to be designed to withstand is much less than the loading force subjected upon a satellite launched into Earth orbit via a kinetic launcher.

Embodiments of the present disclosure describe structural design changes and ruggedization systems and methods that are necessary for kinetically launched satellites. Firstly, due to the extreme high loading force generated during launch of a kinetically launched satellite, solar panels (as well as other components) on the satellite need to be specifically designed to withstand the high forces while maintaining structural integrity.

Generally, during a launch process from a kinetic launcher, such as centripetal launcher, a solar panel on the top of the satellite can deflect inwards, causing damage to the structural integrity of the solar cells on the solar panel. In particular, the inward deflection can cause damage to the extremely thin (0.05 to 0.5 mm, typically 0.1 mm) layer of coverglass that coats the solar cells to protect them from the harsh radiation environment of space. The coverglass, a very thin layer of doped glass, is generally the first element of the solar cell to endure structural failure during a kinetic launch due to its low tensile strength and brittle nature.

Embodiments of the present disclosure provide that the solar cells can maintain structural integrity and functionality in the high g-loading conditions of a kinetic launch as long as the surface that the solar cells are mounted to remains flat during the kinetic launch process. Thus, mechanisms are disclosed herein to stiffen a solar panel placed at the top of the satellite such that the panel remains flat under high g-load conditions and does not deflect inwards during a launch process to an extent that would cause damage to the solar cell's coverglass. Utilizing these methods of fixturing solar cells to the top of a kinetically launched satellite allows the solar cells to survive the acceleration loads of launch and function to generate solar power for the satellite while it is in space. As would be understood by persons of ordinary skill in the art, while the present disclosure describes satellite launch, the ruggedized fixturing methods for solar cells described herein may also be utilized with other types of payloads that are not specifically satellites.

In exemplary embodiments of the present disclosure, solar cells are bonded to either a panel of a satellite body, or to a deployable panel that is supported by the satellite body. Typically, solar cells may be bonded to the satellite using silicone adhesive or double-sided polyimide tape. However, as would be understood by persons of ordinary skill in the art, other suitable materials for bonding solar cells to a satellite may also be used in addition to, or instead of, the specific components listed here.

Typically, the largest contribution to solar panel deformation is not the weight of the solar cell itself, but rather the weight of the panel upon which the solar cells are mounted. Panel deformation can be mitigated by constructing the panel itself of structural materials with a high stiffness per unit density (specific stiffness), before solar cells are affixed to it. Exemplary suitable high-specific-stiffness structural materials include carbon fiber composite, titanium, or high strength aluminum alloy. As would be understood by persons of ordinary skill in the art, other suitable materials may also be used in addition to, or instead of, the specific components listed here.

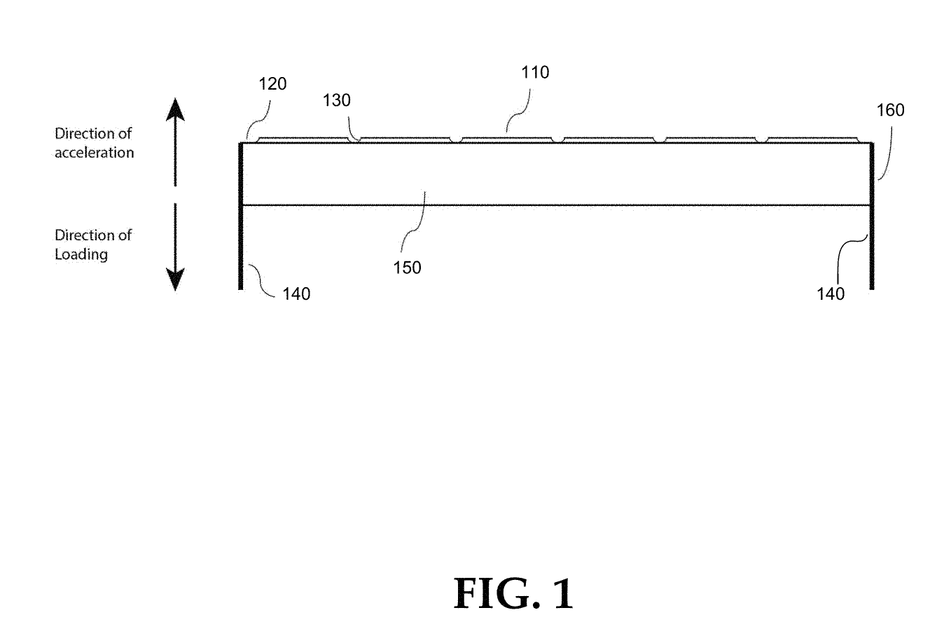

FIG. 1 depicts a side view of an exemplary embodiment of a plurality of solar cells affixed on a solar panel (also referred to herein as simply “panel”) on top of a kinetically launched satellite. While the depicted panel is on top of a satellite in the figure, the panel can also be on a deployable panel or on other sides of the satellite, in various embodiments. In FIG. 1, a plurality of solar cells, 110, are depicted on top of a top panel 120 of a satellite. The solar cells 110 are affixed to the top panel 120 of the satellite via adhesive bonding 130. A person of ordinary skill in the art would understand that other bonding mechanisms may be used instead of, or in addition to, adhesive bonding in various embodiments.

In exemplary FIG. 1, side panels 140 are part of the primary satellite structure, and a stiffening assembly 150 and top panel 120 are placed on top of the primary satellite structure. The top panel 120 of the satellite can be “stiffened” (i.e. reinforced such that it deflects minimally under load) by the stiffening assembly 150, which may or may not include support members (not depicted). The stiffened panel (including stiffening assembly) is held on top of the satellite by a support structure. The side panel(s) 140 of the satellite are one of many possible embodiments of a support structure for the top panel 120 and stiffening assembly 150. Together these components prevent inward deflection of the top panel 120 during the high G-forces generated during a kinetic launch. A person of ordinary skill in the art would understand that the top panel 120 of the satellite can be supported by other structures in addition to these components, in various embodiments.

In FIG. 1, the stiffening assembly 150 is depicted as a generic structure. However, in exemplary embodiments, the stiffening assembly 150 can consist of a foam or honeycomb “sandwich panel” structure that the top panel 120 of the satellite is laminated into. This sandwich panel structure of the stiffening assembly 150 provides stiffening of the top panel 120 to aid in maintenance of structural integrity, and mitigation of inward deflection, during the high acceleration force conditions generated during a kinetic launch of a satellite into Earth orbit or beyond. The stiffening assembly 150 has a terminal end 160 attached to the side panel 140 of the satellite in exemplary FIG. 1. While only one terminal end is specifically noted in exemplary FIG. 1, the stiffening assembly 150 may connect to one or more side panels 140 on the satellite, including up to all side panels of the top surface of a satellite structure. In other embodiments, the top panel stiffening assembly may extend past one or more side panels of a satellite structure.

Further, while not explicitly depicted in FIG. 1, stiffening assembly 150 can also include support members (also referred to herein as support beams or stringers) attached to the side panels 140 of the satellite in various embodiments, to provide additional stiffening of the top panel 120. In exemplary embodiments, the stiffening assembly 150 can include support beams that run along the base of the top panel 120, from one side panel 140 to another. In this embodiment, the support beams prevent overall deflection of the top panel 120 and a thinner “sandwich panel” laminate of the stiffening assembly 150 prevents deflection of the top panel 120 between the support beams.

In exemplary embodiments, the stiffening assembly attaches to the support structure for the top panel 120 in such a way that the bending moment exerted from the top panel 120 is transferred directly to the support structure. This adds stiffness to the top panel 120 and reduces the amount of reinforcing material required. When using support members as part of the stiffening assembly 150 supported by the satellite side panels, bending moment transfer can be achieved by rigidly attaching the ends of the support members to the side panels 140.

Exemplary support beams can be straight-edged, arched, or of other varying shapes, in various embodiments. If support beams are utilized under the top panel 120, they are also constructed of a high-specific-stiffness structural material, similar to the material used for the top panel 120. In exemplary embodiments, the support beams may be constructed of the same material, or different material than the top panel 120. With the stiffening assembly 150 and its light weight as a result of being constructed of high-specific-stiffness materials (such as carbon fiber composite), the top panel 120 is stiffened, such that it remains flat under the high acceleration forces (>5,000 times Earth's gravity) generated during a kinetic launch of a satellite into Earth orbit or beyond.

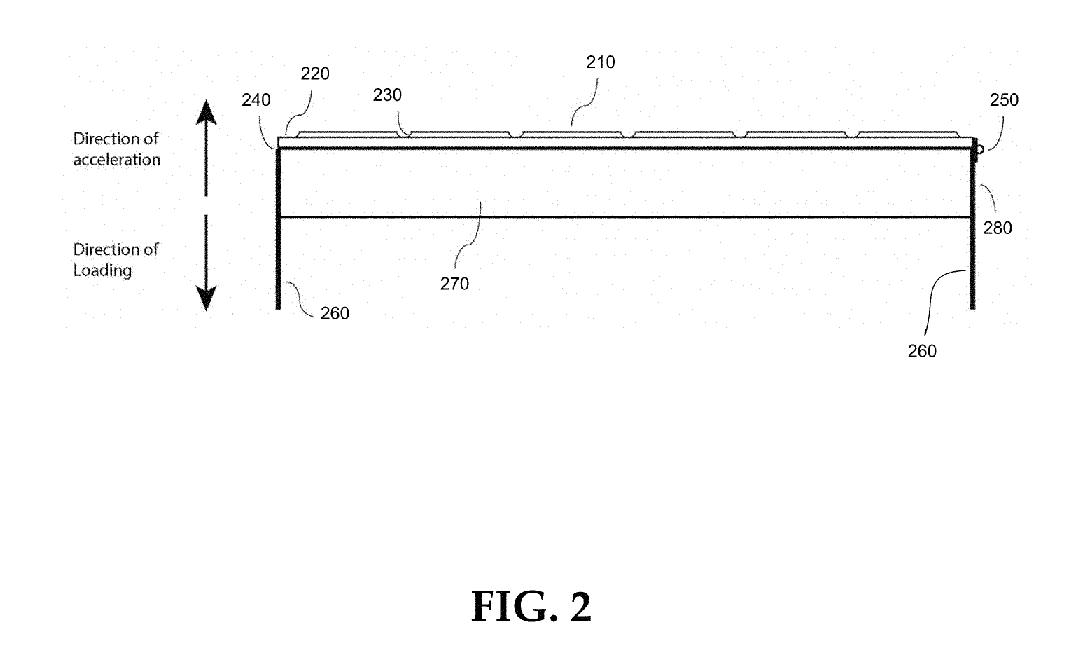

FIG. 2 depicts a side view of an exemplary embodiment of a plurality of solar cells affixed on a deployable solar panel that rests on the top of a kinetically launched satellite while stowed. While the depicted deployable solar panel is on top of a satellite in the figure, a deployable solar panel can be on other sides of the satellite, in addition to, or instead of, on top of the satellite. In FIG. 2, a plurality of solar cells, 210, are depicted on top of a deployable solar panel 220 of a satellite. The solar cells 210 are attached to the deployable solar panel 220 of the satellite via adhesive bonding 230. A person of ordinary skill in the art would understand that other bonding mechanisms may be used instead of, or in addition to, adhesive bonding in various embodiments.

In exemplary FIG. 2, side panels 260 are part of the primary satellite structure, and the solar cells 210, stiffened top panel 240, and stiffening assembly 270 are all components of the solar panel placed on top of the primary satellite structure. The deployable solar panel 220 is affixed to a stiffened satellite top panel 240 via a deployment hinge 250. As would be understood by persons of ordinary skill in the art, while a “hinge” is depicted in FIG. 2, other mechanical means of affixing the deployable solar panel 220 to the primary satellite structure may be used instead of, or in addition to, a hinge. Further, while the side view of FIG. 2 depicts one hinge, there may be a plurality of hinges utilized. The deployment hinge 250 allows the deployable solar panel 220 to swing outwards once the satellite is in outer space, to provide solar electricity to the satellite. Once deployed, the deployable solar panel 220 extends from the body of the satellite.

Deformation of the deployable solar panel 220 is prevented by being supported by the stiffened top panel 240 of the satellite that it rests upon. A stiffening assembly 270 reinforces the top panel of the satellite such that it is able to support the deployable panel without deforming to a degree that would result in damage to the solar cells 210.

In FIG. 2, the stiffening assembly 270 is depicted as a generic structure. However, in exemplary embodiments, the top panel stiffening assembly 270 can consist of laminating the deployable solar panel 220 into a foam or honeycomb “sandwich panel” structure. Terminal ends 280 of the stiffening assembly 270 are attached to the side panel 260. This provides stiffening of the deployable solar panel 220 and top panel 240 to aid in maintenance of structural integrity under the high acceleration force conditions generated during a kinetic launch of a satellite into Earth orbit or beyond. While only one terminal end is specifically noted in exemplary FIG. 2, the stiffening assembly 270 may connect to one or more side panels 260 on the satellite, including up to all side panels of the top surface of a satellite structure. In other embodiments, the top panel stiffening assembly may extend past one or more side panels of a satellite structure.

Further, while not explicitly depicted in FIG. 2, the top panel stiffening assembly 270 can include support beams ((also referred to herein as stringers or support members) that run along the base of the top panel 240. Attaching the ends of these support beams to one or more side panels 260 provides a means of transferring bending moment in the panel to the primary structure of the satellite, thereby adding stiffness to the panel and reducing material requirements for the stiffening assembly 270.

Exemplary support beams can be straight-edged, arched, or of other varying shapes, in various embodiments. If support beams are utilized under the top panel 240, they may also be constructed of a high-specific-stiffness structural material, similar to the material used for the top panel 240. In exemplary embodiments, the support beams may be constructed of the same material, or different material than the top panel 240. With the stiffening assembly 270 and its light weight as a result of being constructed of high-specific-stiffness materials (such as carbon fiber composite), the top panel 240 is stiffened, such that it remains flat under the high quasi-static acceleration forces (>5,000 times Earth's gravity) generated during a kinetic launch of a satellite into Earth orbit or beyond. In exemplary embodiments, deployable solar panels 220 on top of the satellite do not require additional stiffening so long as they are resting on a top panel 240 of the satellite body that is sufficiently resistant to bending.

In exemplary embodiments, a solar cell of this disclosure may have a dimension of approximately 80 mm×40 mm. A solar panel may have a dimension of approximately 40 cm×40 cm×35 cm and may contain approximately 30-36 solar cells on it. An exemplary satellite, such as the satellite 300, can weigh approximately 5 kg-100 kg. As would be understood by a person of ordinary skill in the art, while these specific dimensions are listed here, solar cells and solar panels may have dimensions outside of the listed range and still be within the scope of this disclosure. Additionally, satellites may be outside of the listed range for weight and still be within the scope of this disclosure.

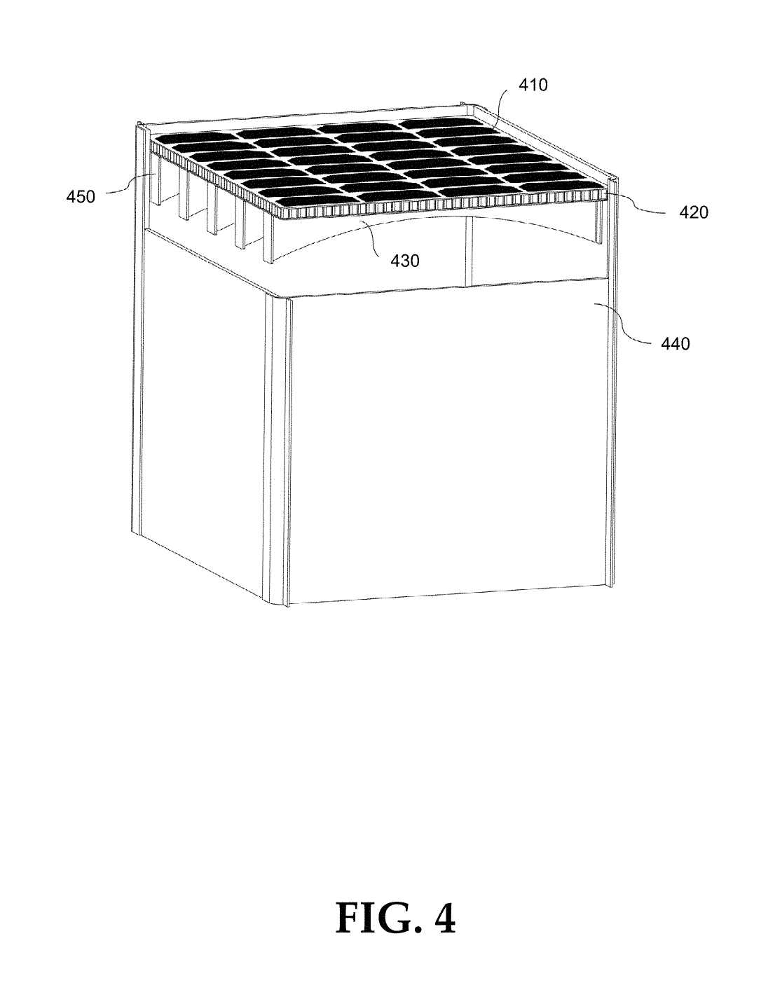

FIG. 4 depicts an exemplary embodiment of a solar panel fixtured on a top panel of a kinetically launched satellite, utilizing support beams. In the figure, there are a plurality of solar cells 410 adhesively bonded to the top panel of the satellite. A top panel 420 is constructed of high-specific-stiffness structural material, such as carbon fiber composite, that is laminated into a “sandwich panel” structure using honeycomb cores or foam cores). The sandwich panel structure provides stiffening of the top panel 420 to aid in preventing deflection of the top panel 420 between support beams. As would be understood by persons of ordinary skill in the art, other types of mechanisms may also be used to create the sandwich panel, other than honeycomb or foam cores.

Support beams 430 are provided under the top panel 420 to prevent general deflection of the panel. While five support beams running across the length of the top panel 420 are depicted in the figure, there can be fewer or additional support beams utilized in potentially different orientations, depending on the size and/or weight of the satellite, among other factors. Further, while the support beams 430 in the figure are arched, the support beams 430 may be of different shapes in various embodiments. For example, support beams 430 may be straight-edged (such as I-beams), or of any other suitable shape.

Satellite side panels 440 provide a support structure for the top panel 420 and stiffening assembly. As used herein, the stiffening assembly in this exemplary embodiment comprises the sandwich panel structure in combination with the support beams 430. Support beams 430 are attached to the side panels 440 at attachment point 450. While only one attachment point is specifically noted in the figure, a person of ordinary skill in the art would understand that each of the support beams 430 is attached to the side panels 440 at both ends, allowing it to transfer bending moment to the support structure for the top panel and stiffening assembly (in this case, the side panels 440 of the satellite).

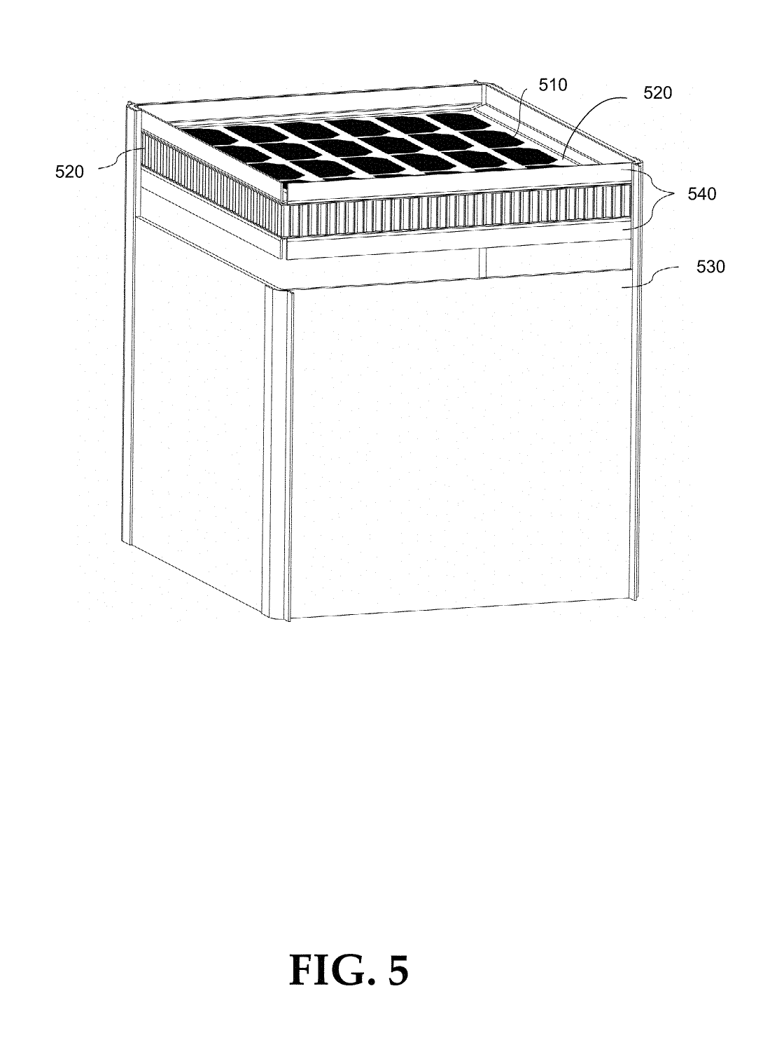

FIG. 5 depicts an exemplary embodiment of a solar panel fixtured on a top panel of a kinetically launched satellite, without utilizing any support beams. In the figure, there are a plurality of solar cells 510 adhesively bonded to the top panel of the satellite. A top panel 520 is constructed of high-specific-stiffness structural material, such as carbon fiber composite, that is laminated into a sandwich panel structure using honeycomb or foam core. The sandwich panel is thick enough that it can remain flat and maintain its structural integrity under the high acceleration loads of kinetic launch, without needing support beams underneath.

Typical sandwich panels used on the exterior of satellites are less than 1 cm thick, whereas the sandwich panel in this exemplary design is over 3 cm thick. In exemplary embodiments, finite element analysis can be utilized to determine a suitable thickness for the sandwich panel (i.e., the stiffening assembly in this exemplary embodiment). In this way, the sandwich panel structure is sufficient by itself to provide stiffening of the top panel 520 to prevent deflection of the top panel 520, without the need for any support beams, and the sandwich panel serves as the stiffening assembly part of the support structure for the top panel 520 of the satellite. As would be understood by persons of ordinary skill in the art, other types of mechanisms may also be used to create the sandwich panel, other than honeycomb or foam cores.

Satellite side panels 530 provide a support structure for the top panel 520 and stiffening assembly. Bracket elements 540 attach the top panel 520 to the support structure. The bracket elements 540 help to support the top panel 520 under compression loading and transfer bending moment of the top panel 520 to the support structure. As would be understood by persons of ordinary skill in the art, other types of mechanisms may also be used to attach the top panel 520 to the support structure, other than brackets.

Exemplary FIG. 5 depicts empty space between bracket elements 540 and the satellite side panels 530. As would be understood by persons of ordinary skill in the art, the amount of empty space may be greater or less than depicted in the exemplary figure. In various embodiments, there may be no empty space between bracket element 540 and a satellite side panel 530.

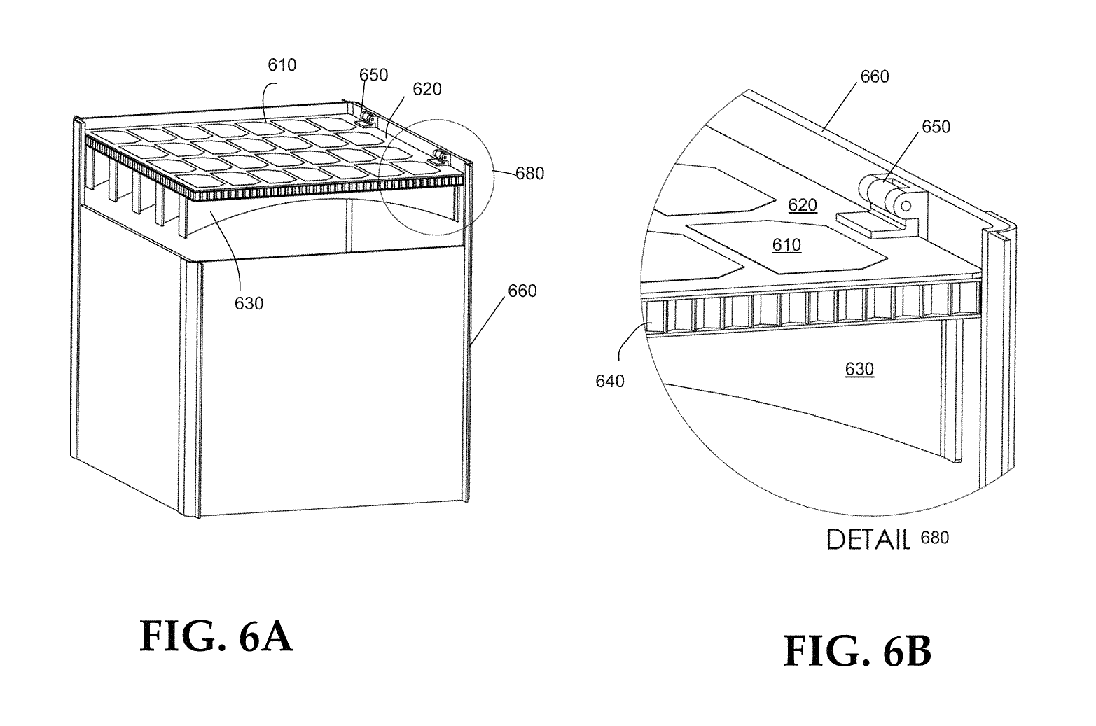

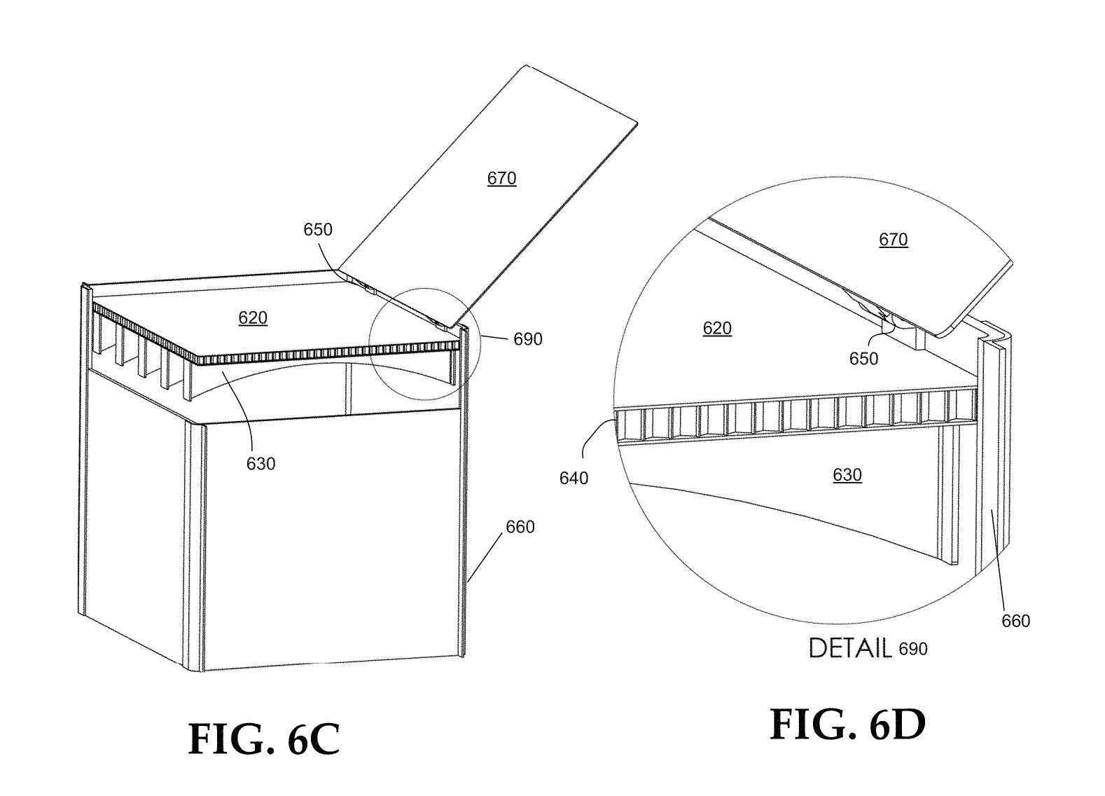

FIGS. 6A and 6B depict an exemplary embodiment of a deployable solar panel fixtured on a top panel of a kinetically launched satellite, utilizing support beams. In the figures, there are a plurality of solar cells 610 adhesively bonded to the top panel of the satellite. A top panel 620 is constructed of high-specific-stiffness structural material, such as carbon fiber composite. The stiffening assembly comprises a “sandwich panel” 640 and support beams 630. The sandwich panel structure uses honeycomb cores or foam cores, and is constructed of the same or different high-specific-stiffness material as the top panel 620. The sandwich panel structure provides stiffening of the top panel 620 to aid in preventing deflection of the top panel 620 between support beams. As would be understood by persons of ordinary skill in the art, other types of mechanisms may also be used to create the sandwich panel 640, other than honeycomb or foam cores.

Support beams 630 are provided under the top panel 620 to prevent general deflection of the panel. While five support beams running across the length of the underside of the top panel 620 are depicted in the figure, there can be fewer or additional support beams utilized in potentially different orientations, depending on the size and/or weight of the satellite, among other factors. Further, while the support beams 630 in the figure are arched, the support beams 630 may be of different shapes in various embodiments. For example, support beams 630 may be straight-edged (such as I-beams), or of any other suitable shape. The stiffening assembly (comprising the sandwich panel 640 and the support beams 640) aids in mitigating deflection of the top panel 620 during kinetic launch, thereby maintaining the structural integrity and functionality of the solar cells 610 bonded to the top panel 620.

FIGS. 6A and 6B also depict two deployment hinges 650, which allow the deployable solar panel to swing outwards when the satellite is in outer space. Further, support beams 630 are attached to the side panels 660 at both ends, allowing bending moment in the panel to be transferred to the support structure for the top panel and stiffening assembly. FIG. 6B depicts a close-up view of detail 680 from FIG. 6A.

FIGS. 6C and 6D depict another view of a deployable solar panel fixtured on a top panel of a kinetically launched satellite, utilizing support beams. In the figures, the deployable solar panel 670 extends outwards from the top panel 620 and the satellite bus, after deployment in outer space. While not depicted in the figures, a plurality of solar cells are adhesively bonded to the top panel 620 of the satellite. A top panel 620 is constructed of high-specific-stiffness structural material, such as carbon fiber composite. The stiffening assembly comprises a “sandwich panel” 640 and support beams 630. The sandwich panel structure uses honeycomb cores or foam cores, and is constructed of the same or different high-specific-stiffness material as the top panel 620. The sandwich panel structure provides stiffening of the top panel 620 to aid in preventing deflection of the top panel 620 between support beams. As would be understood by persons of ordinary skill in the art, other types of mechanisms may also be used to create the sandwich panel 640, other than honeycomb or foam cores.

Support beams 630 are provided under the top panel 620 to prevent general deflection of the panel. While five support beams running across the length of the underside of the top panel 620 are depicted in the figure, there can be fewer or additional support beams utilized in potentially different orientations, depending on the size and/or weight of the satellite, among other factors. Further, while the support beams 630 in the figure are arched, the support beams 630 may be of different shapes in various embodiments. For example, support beams 630 may be straight-edged (such as I-beams), or of any other suitable shape.

The stiffening assembly (comprising the sandwich panel 640 and the support beams 640) aids in mitigating deflection of the top panel 620 during kinetic launch, thereby maintaining the structural integrity and functionality of the solar cells 610 bonded to the top panel 620.

FIGS. 6C and 6D also depict two deployment hinges 650, which allow the deployable solar panel to swing outwards when the satellite is in outer space. Further, support beams 630 are attached to the side panels 660 at both ends, allowing bending moment in the panel to be transferred to the support structure for the top panel and stiffening assembly. FIG. 6D depicts a close-up view of detail 690 from FIG. 6C.

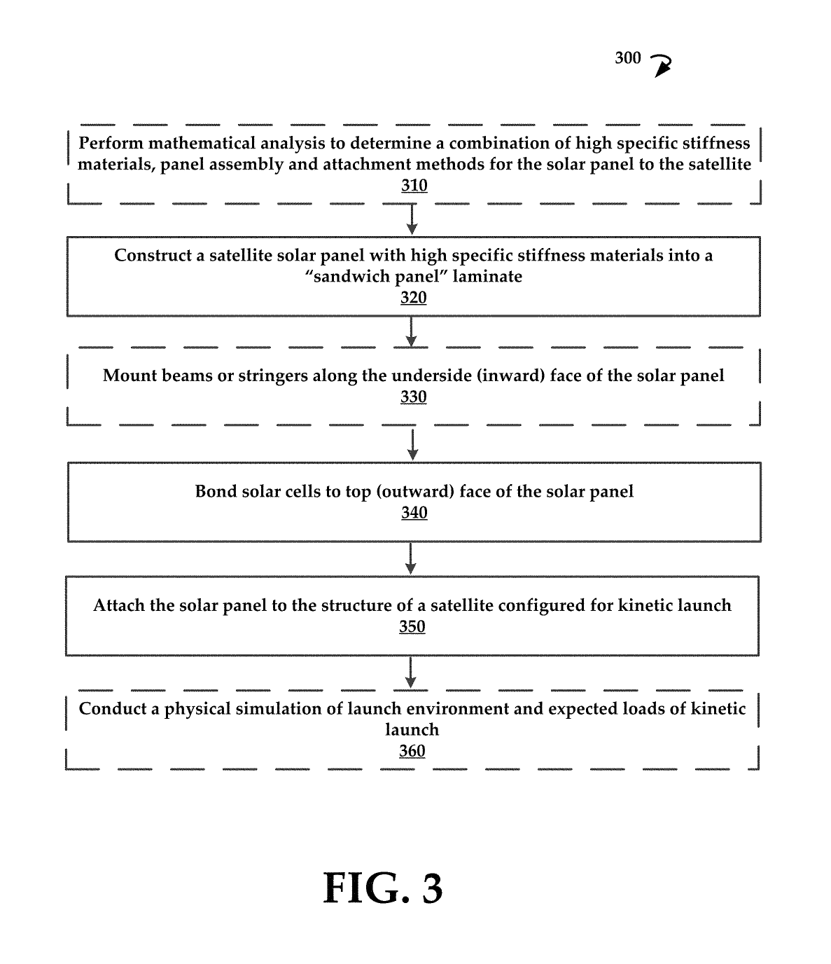

FIG. 3 depicts an exemplary method 300 for providing ruggedized solar panels on top of a kinetically launched satellite. With this method, the solar cells can withstand quasi-static acceleration forces of at least 5,000 times Earth's gravity, in the same direction of loading, during a kinetic launch and maintain structural integrity and functionality of the solar cells.

In optional step 310, a mathematical analysis is performed to determine a combination of high specific stiffness materials, solar panel assembly and attachment methods for the solar panel to the top of the satellite. The mathematical analysis allows for the determination of the configuration and composition of components such that they will endure the loads of kinetic launch and not deform to a degree that would result in damage to solar cells bonded to the solar panel. In step 320, a solar panel is constructed of materials with high specific stiffness into a “sandwich panel” laminate. As disclosed herein, the sandwich solar panel can be of a foam or honeycomb structure.

In optional step 330, a plurality of beams or stringers are mounted along the underside (inward) face of the satellite solar panel, as part of a stiffening assembly for the solar panel. The plurality of support beams are made from the same or different high-specific-stiffness material as the solar panel itself. In various embodiments, the support beams may be arched or straight-edged in shape.

In step 340, a plurality of solar cells are bonded to the top (outward) face of the solar panel. In step 350, the solar panel is attached to a satellite structure that is configured for kinetic launch in such a way that it is supported sufficiently for kinetic launch, and the bending moment of the solar panel is transferred to the structure of the satellite where the solar panel attaches to the satellite. In optional step 360, a physical simulation of the launch environment is conducted to expose the solar panel and satellite structure to the expected loads of kinetic launch, in order to confirm the maintenance of the integrity of the solar panel and the solar cells bonded to it.

Method and apparatuses have been disclosed herein to provide ruggedized solar cells on satellites configured for a kinetic space launch. While the disclosure describes various embodiments of satellites, the ruggedized solar cell assembly may also be applied to other types of payloads that are launched kinetically. With this disclosure, the ruggedized solar cell assembly can withstand static or quasi-static acceleration forces of over 5,000 times Earth's gravity, in a single direction roughly perpendicular to the surface of the solar cells.

While specific embodiments of, and examples for, the system are described above for illustrative purposes, various equivalent modifications are possible within the scope of the system, as those skilled in the relevant art will recognize. For example, while processes or steps are presented in a given order, alternative embodiments may perform routines having steps in a different order, and some processes or steps may be deleted, moved, added, subdivided, combined, and/or modified to provide alternative or sub-combinations. Each of these processes or steps may be implemented in a variety of different ways. Also, while processes or steps are at times shown as being performed in series, these processes or steps may instead be performed in parallel, or may be performed at different times.

While various embodiments have been described above, it should be understood that they have been presented by way of example only, and not limitation. The descriptions are not intended to limit the scope of the invention to the particular forms set forth herein. To the contrary, the present descriptions are intended to cover such alternatives, modifications, and equivalents as may be included within the spirit and scope of the invention as defined by the appended claims and otherwise appreciated by one of ordinary skill in the art. Thus, the breadth and scope of a preferred embodiment should not be limited by any of the above-described exemplary embodiments.

What is claimed is:

1. A ruggedized solar panel assembly for placement on top of a kinetically launched satellite that is configured to withstand a quasi-static acceleration load during a kinetic launch of at least 5,000 times Earth's gravity, the solar panel assembly comprising:
a top panel stiffening assembly of a sandwich panel structure constructed of a high-specific-stiffness material, the top panel stiffening assembly having a top surface and a bottom surface; and
a plurality of solar cells adhesively bonded to the top surface of the top panel stiffening assembly.

2. The solar panel assembly of claim 1, wherein the top panel stiffening assembly further comprises a plurality of support beams under the bottom surface of the top panel stiffening assembly.

3. The solar panel assembly of claim 2, wherein the plurality of support beams are arched in shape.

4. The solar panel assembly of claim 2, wherein the plurality of support beams are straight-edged in shape.

5. The solar panel assembly of claim 1, wherein the high-specific-stiffness material of the top panel stiffening assembly is a carbon fiber composite material.

6. The solar panel assembly of claim 1, wherein the sandwich panel structure of the top panel stiffening assembly of the satellite is a honeycomb sandwich panel structure laminate.

7. The solar panel assembly of claim 1, wherein the sandwich panel structure of the top panel stiffening assembly of the satellite is a foam core sandwich panel structure laminate.

8. The solar panel assembly of claim 1, wherein the kinetic launch is via a centripetal launcher.

9. The solar panel assembly of claim 1 wherein the acceleration load of launch is applied to the satellite in compression.

10. A ruggedized solar panel assembly for placement on top of a kinetically launched satellite that is configured to withstand a quasi-static acceleration load of at least 5,000 times Earth's gravity during a kinetic launch, the solar panel assembly comprising:
a top panel stiffening assembly of a sandwich panel structure constructed of a high-specific-stiffness material, the top panel stiffening assembly having a top surface and a bottom surface;
a deployable solar panel attached to the top surface of the top panel stiffening assembly via at least one deployment hinge; and
a plurality of solar cells adhesively bonded to the deployable solar panel.

11. The solar panel assembly of claim 10, wherein the top panel stiffening assembly further comprises a plurality of support beams attached to the bottom surface of the top panel stiffening assembly.

12. The solar panel assembly of claim 11, wherein the plurality of support beams are arched in shape.

13. The solar panel assembly of claim 11, wherein the plurality of support beams are straight-edged in shape.

14. The solar panel assembly of claim 10, wherein the high-specific-stiffness material of the top panel stiffening assembly is a carbon fiber composite material.

15. The solar panel assembly of claim 10, wherein the sandwich panel structure of the top panel stiffening assembly of the satellite is a honeycomb sandwich panel structure laminate.

16. The solar panel assembly of claim 10, wherein the sandwich panel structure of the top panel stiffening assembly of the satellite is a foam core sandwich panel structure laminate.

17. The solar panel assembly of claim 10, wherein the solar panel assembly is affixed to the top of a kinetically launched satellite.

18. The solar panel assembly of claim 10, wherein the kinetic launch is from a centripetal launcher.

19. The solar panel assembly of claim 10 wherein the acceleration load of launch is applied to the satellite in compression.
